(19) United States
(12) Patent Application Publication
(10) Pub. No.: US 2026/0332023 A1
(43) Pub. Date: Oct. 22, 2026

(54) INPUT POWER SUPPLY CIRCUIT HAVING INPUT POWER SUPPLYING FREQUENCY CONTROL MECHANISM

(71) Applicant: ANPEC ELECTRONICS CORPORATION, HSINCHU (TW)

(72) Inventors: CHIH-NING CHEN, TAIPEI CITY (TW); CHIH-HENG SU, Hsinchu City (TW)

(21) Appl. No.: 19/253,982

(22) Filed: Jun. 30, 2025

(30) Foreign Application Priority Data
Apr. 18, 2025 (TW) 114114701

(51) Int. Cl. H02M 1/00; H03K 3/356

(52) U.S. Cl. CPC H02M 1/0025; H02M 1/0009; H03K 3/356008; H03K 3/356026

(57) ABSTRACT

An input power supply circuit having an input power supplying frequency control mechanism includes an input switch, a current sensing circuit, a clock signal generator circuit and a charging circuit. A first terminal of the input switch is coupled to an input voltage. The current sensing circuit senses a total input current flowing from a second terminal of the input switch to output an input current sensed signal. The clock signal generator circuit sets frequencies of a plurality of pulse waves of a charging clock signal according to the input current sensed signal. The charging circuit outputs a charging signal to a control terminal of the input switch based on the frequencies of the pulse waves of the charging clock signal.

### CROSS-REFERENCE TO RELATED PATENT APPLICATION

This application claims the benefit of priority to Taiwan Patent Application No. 114114701, filed on Apr. 18, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an input power supply circuit, and more particularly to an input power supply circuit having an input power supplying frequency control mechanism.

### BACKGROUND OF THE DISCLOSURE

Power converters are indispensable for electronic devices. The power converters are used for converting input voltages from input power supply circuits and supplying the converted input voltages as output voltages to the electronic devices.

However, charger circuits of conventional input power supply circuits supply a fixed amount of input power to the electronic devices based on a fixed frequency of a preset clock signal. The conventional input power supply circuits do not, according to an amount of the input power required for the electronic devices, adjust an amount and a supply frequency of the input power supplied to the electronic devices. In particular, the input power supplied by the conventional input power supply circuits is not decreased when the input power required for electronic devices is decreased. At this time, unnecessary power is consumed in the conventional input power supply circuits.

### SUMMARY OF THE DISCLOSURE

In response to the above-referenced technical inadequacies, the present disclosure provides an input power supply circuit having an input power supplying frequency control mechanism. The input power supply circuit includes an input switch, a current sensing circuit, a clock signal generator circuit and a charging circuit. A first terminal of the input switch is coupled to an input voltage. A second terminal of the input switch is connected to a power receiving terminal of each of a plurality of power receiving circuits. The current sensing circuit is connected to the second terminal of the input switch. The current sensing circuit is configured to sense a total input current flowing from the second terminal of the input switch to output an input current sensed signal. The clock signal generator circuit is connected to the current sensing circuit. The clock signal generator circuit is configured to set a frequency of each of a plurality of pulse waves of a charging clock signal according to the input current sensed signal. The charging circuit is connected to the clock signal generator circuit and a control terminal of the input switch. The charging circuit is configured to output a charging signal to the control terminal of the input switch based on the frequency of each of the plurality of pulse waves of the charging clock signal.

As described above, the present disclosure provides the input power supply circuit having the input power supplying frequency control mechanism. In the input power supply circuit of the present disclosure, the charging circuit reduces a frequency of charging a voltage of the control terminal of the input switch, according to a decrease in the total input current that is obtained from the second terminal of the input switch by the plurality of power receiving circuits (such as power converters). As a result, the input power supply circuit of the present disclosure only supplies an appropriate amount of power, and not excessive power, to the plurality of power receiving circuits. Therefore, the input power supply circuit of the present disclosure is prevented from unnecessarily consuming power for effectively saving power. Furthermore, if the input power supply circuit of the present disclosure further includes the main controller circuit, the clock signal generator circuit stops supplying the main clock signal to the main controller circuit in the power saving mode, thereby saving more power.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a circuit diagram of an input power supply circuit having an input power supplying frequency control mechanism and a plurality of power receiving circuits according to a first embodiment of the present disclosure;

FIG. 2 is a circuit diagram of an input power supply circuit having an input power supplying frequency control mechanism and a plurality of power receiving circuits according to a second embodiment of the present disclosure;

FIG. 3 is a circuit diagram of an input power supply circuit having an input power supplying frequency control mechanism and a plurality of power receiving circuits according to a third embodiment of the present disclosure;

FIG. 4 is a circuit diagram of an input power supply circuit having an input power supplying frequency control mechanism according to a fourth embodiment of the present disclosure;

FIG. 5 is a waveform diagram of signals of the input power supply circuit having the input power supplying frequency control mechanism according to the first to fourth embodiments of the present disclosure;

FIG. 6 is a waveform diagram of signals of the input power supply circuit having the input power supplying frequency control mechanism according to the first to fourth embodiments of the present disclosure;

FIG. 7 is a circuit diagram of a clock synchronizing circuit of an input power supply circuit having an input power supplying frequency control mechanism according to a fifth embodiment of the present disclosure;

FIG. 8 is a waveform diagram of signals of the clock synchronizing circuit of the input power supply circuit having the input power supplying frequency control mechanism according to the fifth embodiment of the present disclosure; and

FIG. 9 is a waveform diagram of signals of the input power supply circuit having the input power supplying frequency control mechanism according to the first to fifth embodiments of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

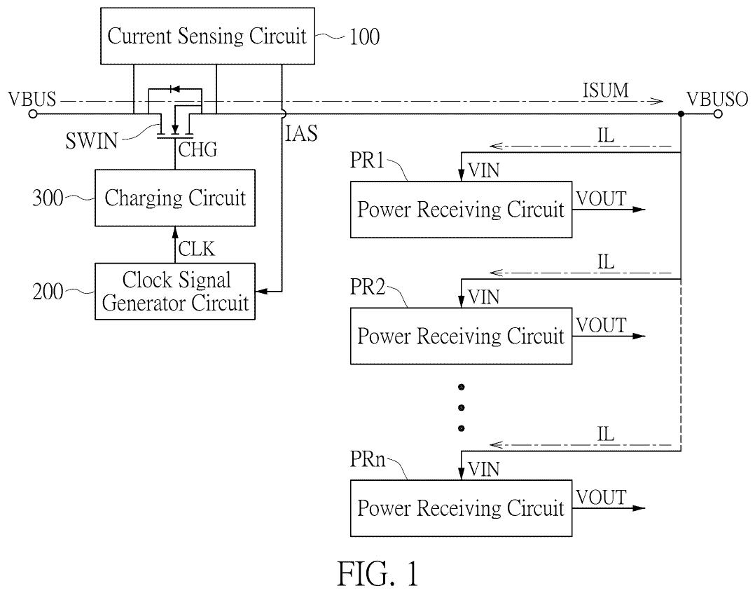

Reference is made to FIG. 1, which is a circuit diagram of an input power supply circuit having an input power supplying frequency control mechanism and a plurality of power receiving circuits according to a first embodiment of the present disclosure.

The input power supply circuit of the present disclosure is applicable to supply a plurality of input currents IL respectively to a plurality of power receiving circuits PR1 to PRn as shown in FIG. 1. The plurality of power receiving circuits PR1 to PRn are a plurality of loads of the input power supply circuit of the present disclosure. Each of the plurality of power receiving circuits PR1 to PRn may be any electronic circuit such as, but not limited to, a power converter.

A plurality of output terminals of the plurality of power receiving circuits PR1 to PRn may respectively supply a plurality of output voltages VOUT to a plurality of electronic devices. The plurality of electronic devices are a plurality of loads of the plurality of power receiving circuits PR1 to PRn. It should be understood that, the amount of the input current IL required for each one of the plurality of power receiving circuits PR1 to PRn depends on the amount of power required for operation of the electronic device connected to the one of the plurality of power receiving circuits PR1 to PRn.

It is worth noting that, the input power supply circuit of the present disclosure is able to appropriately modulate a current value and a supply frequency of a total input current ISUM, according to the amount of the total input current ISUM of the plurality of input currents IL that are respectively obtained by the plurality of power receiving circuits PR1 to PRn from the input power supply circuit.

In order to appropriately modulate the current value and the supply frequency of the total input current ISUM supplied to the plurality of power receiving circuits PR1 to PRn, the input power supply circuit of the present disclosure includes an input switch SWIN, a current sensing circuit 100, a clock signal generator circuit 200 and a charging circuit 300 as shown in FIG. 1.

A first terminal (such as a drain terminal) of the input switch SWIN is coupled to an input voltage VBUS. A second terminal (such as a source terminal) of the input switch SWIN is used as an output terminal of the input power supply circuit of the present disclosure. A voltage of the second terminal (such as the source terminal) of the input switch SWIN is used as an output voltage VBUSO.

The second terminal of the input switch SWIN as the output terminal of the input power supply circuit is connected to a power receiving terminal of each of the plurality of power receiving circuits PR1 to PRn. The input power supply circuit of the present disclosure is configured to supply the total input current ISUM, and then the total input current ISUM is divided into the plurality of input currents IL that respectively flow to the plurality of power receiving circuits PR1 to PRn.

Further, after each of the plurality of power receiving circuits PR1 to PRn receives the input current IL from the input power supply circuit of the present disclosure, each of the plurality of power receiving circuits PR1 to PRn uses or converts the input current IL to supply the output voltage VOUT to the electronic device connected thereto.

The current sensing circuit 100 is connected to or contacts the second terminal (and the first terminal) of the input switch SWIN. The current sensing circuit 100 senses the total input current ISUM flowing from the second terminal of the input switch SWIN to output an input current sensed signal IAS.

A first input terminal of the clock signal generator circuit 200 is connected to an output terminal of the current sensing circuit 100. The clock signal generator circuit 200 sets a frequency of each of a plurality of pulse waves of a charging clock signal CLK according to the input current sensed signal IAS from the current sensing circuit 100.

An input terminal of the charging circuit 300 is connected to a charging clock output terminal of the clock signal generator circuit 200 and a control terminal of the input switch SWIN. The charging circuit 300 outputs a charging signal CHG to the control terminal of the input switch SWIN, based on the frequency of each of the plurality of pulse waves of the charging clock signal CLK from the clock signal generator circuit 200. The charging signal CHG is a voltage signal or a current signal.

The charging circuit 300 of the input power supply circuit of the present disclosure, according to the input current sensed signal IAS from the current sensing circuit 100, determines a change in the total input current ISUM that is obtained from the second terminal of the input switch SWIN by the plurality of power receiving circuits PR1 to PRn. The charging circuit 300, according to the change in the total input current ISUM, modulates a frequency of charging a voltage of the control terminal of the input switch SWIN so as to modulate an operation state of the input switch SWIN. As a result, the amount and the supply frequency of the total input current ISUM supplied to the plurality of power receiving circuits PR1 to PRn are modulated.

The more the power is required for the electronic devices connected respectively to the output terminals of the plurality of power receiving circuits PR1 to PRn, the larger the total input current ISUM is obtained from the input power supply circuit of the present disclosure by the power receiving terminals of the plurality of power receiving circuits PR1 to PRn. Conversely, the smaller the power is required for the electronic devices connected respectively to the output terminals of the plurality of power receiving circuits PR1 to PRn, the smaller the total input current ISUM is obtained from the input power supply circuit by the power receiving terminals of the plurality of power receiving circuits PR1 to PRn.

When the total input current ISUM obtained by the electronic devices that are respectively connected to the output terminals of the plurality of power receiving circuits PR1 to PRn is increased, the frequency of charging the voltage of the control terminal of the input switch SWIN by the charging circuit 300 is also increased As a result, a conduction state of the input switch SWIN is modulated. For example, the input switch SWIN is turned on for a longer period of time for increasing the total input current ISUM that is supplied through the second terminal of the input switch SWIN to the plurality of power receiving circuits PR1 to PRn.

It is worth noting that, when the total input current ISUM of the second terminal of the input switch SWIN is decreased, the frequency that the voltage of the control terminal of the input switch SWIN is charged by the charging circuit 300 is also reduced. As a result, the conduction state of the input switch SWIN is modulated for reducing the total input current ISUM flowing out from the second terminal of the input switch SWIN. Therefore, under the condition that the plurality of power receiving circuits PR1 to PRn obtain sufficient power, power consumption of the input power supply circuit of the present disclosure is significantly reduced, thereby achieving a power saving effect.

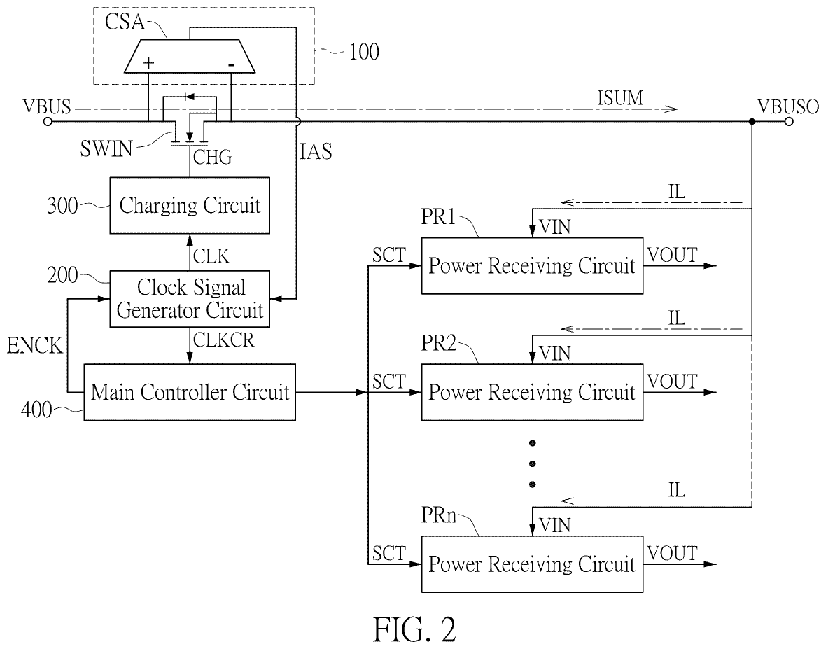

Reference is made to FIG. 2, which is a circuit diagram of an input power supply circuit having an input power supplying frequency control mechanism and a plurality of power receiving circuits according to a second embodiment of the present disclosure.

The descriptions of the second embodiment of the present disclosure that are the same as the descriptions of the first embodiment of the present disclosure are not repeated herein.

A difference between the second and first embodiments of the present disclosure is that, as shown in FIG. 2, the input power supply circuit of the second embodiment of the present disclosure not only includes the input switch SWIN, the current sensing circuit 100, the clock signal generator circuit 200 and the charging circuit 300, but further includes the main controller circuit 400. The current sensing circuit 100 includes a current sensing amplifier CSA. In practice, the current sensing circuit 100 shown in FIG. 1 may also include the current sensing amplifier CSA.

As shown in FIG. 2, a first input terminal such as a non-inverting input terminal of the current sensing amplifier CSA is connected to the second terminal of the input switch SWIN. A second input terminal such as an inverting input terminal of the current sensing amplifier CSA may be connected to the first terminal of the input switch SWIN. The current sensing amplifier CSA senses the total input current ISUM that flows from the first terminal of the input switch SWIN to the second terminal of the input switch SWIN.

An output terminal of the current sensing amplifier CSA is connected to the first input terminal of the clock signal generator circuit 200. The current sensing amplifier CSA multiples the total input current ISUM by a preset gain to output the input current sensed signal IAS to the first input terminal of the clock signal generator circuit 200.

An enable output terminal of the main controller circuit 400 is connected to a second output terminal of the clock signal generator circuit 200. A main clock terminal of the clock signal generator circuit 200 is connected to a clock receiving terminal of the main controller circuit 400. The charging clock output terminal of the clock signal generator circuit 200 is connected to the input terminal of the charging circuit 300.

In a non-power saving mode or the normal mode, the main controller circuit 400 may control the clock signal generator circuit 200 to set the frequency of each of the plurality of pulse waves of the charging clock signal CLK to be equal to the preset frequency, and may output the charging clock signal CLK having the preset frequency to the charging circuit 300.

It is worth noting that, in the power saving mode, the main controller circuit 400 controls the clock signal generator circuit 200 to set the frequencies of the plurality of pulse waves of the charging clock signal CLK according to a current value of the input current sensed signal IAS from the current sensing amplifier CSA, and to output the charging clock signal CLK to the charging circuit 300. The charging circuit 300 outputs the charging signal CHG to the control terminal of the input switch SWIN, based on each of the frequency of the plurality of pulse waves of the charging clock signal CLK from the clock signal generator circuit 200. As a result, when the current value of the input current sensed signal IAS required for the plurality of power receiving circuits PR1 to PRn is decreased, power that is supplied to the plurality of power receiving circuits PR1 to PRn by the charging circuit 300 is effectively reduced, thereby achieving the power saving effect.

In addition, in the non-power saving mode or the normal mode, the main controller circuit 400 may control or enable the clock signal generator circuit 200 to output a main clock signal CLKCR having the preset frequency to the main controller circuit 400 based on the preset frequency of the charging clock signal CLK. That is, a frequency of each of a plurality of pulse waves of the main clock signal CLKCR is equal to the preset frequency. The main controller circuit 400 operates based on the frequencies of the plurality of pulse waves of the main clock signal CLKCR from the clock signal generator circuit 200. That is, the frequency of each of the plurality of pulse waves of the main clock signal CLKCR is used as an operating frequency of the main controller circuit 400.

The main controller circuit 400, based on the frequencies of the plurality of pulse waves of the main clock signal CLKCR, controls operations of the plurality of power receiving circuits PR1 to PRn and processes data from the plurality of power receiving circuits PR1 to PRn. For example, as shown in FIG. 1, the main controller circuit 400 may, based on the frequencies of the plurality of pulse waves of the main clock signal CLKCR, set and output a plurality of main control command signals SCT respectively to the plurality of power receiving circuits PR1 to PRn for controlling the operations of the plurality of power receiving circuits PR1 to PRn.

It is worth noting that, in the power saving mode, the main controller circuit 400 may control the clock signal generator circuit 200 to stop outputting the main clock signal CLKCR to the main controller circuit 400 for reducing workload of the clock signal generator circuit 200, thereby reducing more power consumption of the input power supply circuit of the present disclosure.

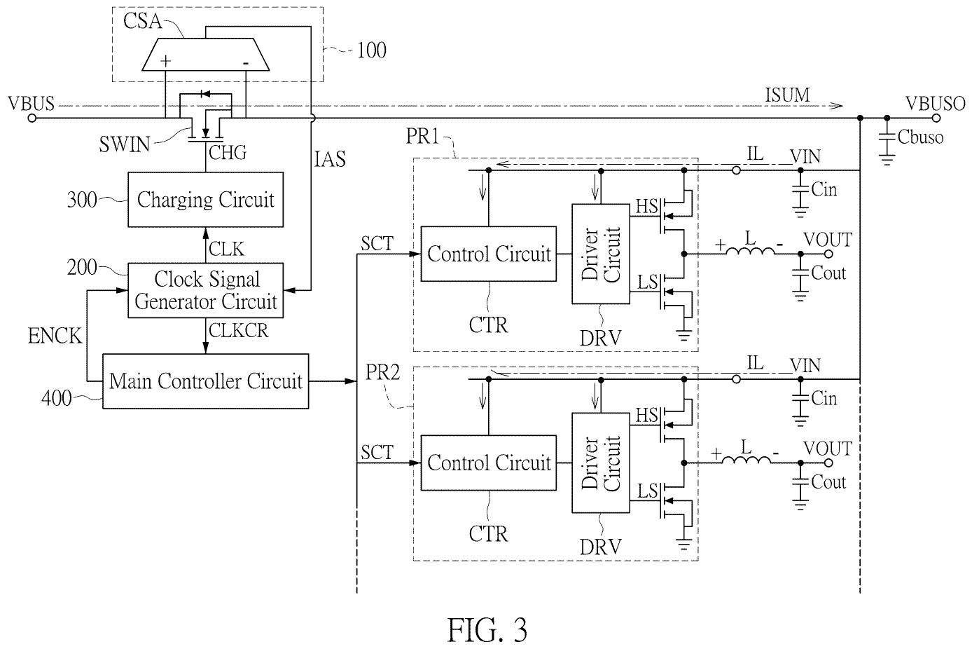

Reference is made to FIG. 3, which is a circuit diagram of an input power supply circuit having an input power supplying frequency control mechanism and a plurality of power receiving circuits according to a third embodiment of the present disclosure.

The descriptions of the third embodiment of the present disclosure that are the same as the descriptions of the first and second embodiments of the present disclosure are not repeated herein.

The input power supply circuit of the present disclosure is applicable to supply the plurality of input currents IL respectively to the two power receiving circuits PR1, PR2 such as the power converters as shown in FIG. 3. For convenience of explanation, only the two power receiving circuits PR1, PR2 are as shown in FIG. 3, but in practice, more power receiving circuits may be included in the input power supply circuit of the present disclosure. Configurations inside the more power receiving circuits may be the same as configurations inside any one of the two power receiving circuits PR1, PR2.

As shown in FIG. 3, in the third embodiment, the input power supply circuit of the present disclosure not only includes the input switch SWIN, the current sensing circuit 100, the clock signal generator circuit 200, the charging circuit 300 and the main controller circuit 400, but further includes an output capacitor Cbuso. In practice, the input power supply circuit of the present disclosure as shown in FIG. 1 and FIG. 2 may also include the output capacitor Cbuso.

As shown in FIG. 3, a first terminal of the output capacitor Cbuso is connected to the second terminal of the input switch SWIN, and a second terminal of the output capacitor Cbuso is grounded.

After the total input current ISUM is divided into the plurality of input currents IL, the power receiving terminals of the two power receiving circuits PR1, PR2 may respectively obtain the plurality of input currents IL from the first terminal of the output capacitor Cbuso or the second terminal of the input switch SWIN.

For example, each of the two power receiving circuits PR1, PR2 may be the power converter including a control circuit CTR, a driver circuit DRV, a high-side switch HS and a low-side switch LS.

A main control terminal of the main controller circuit 400 of the input power supply circuit of the present disclosure is connected to a signal input terminal of the control circuit CTR of each of the plurality of power receiving circuits PR1, PR2. A signal output terminal of the control circuit CTR is connected to a signal input terminal of the driver circuit DRV. A first signal output terminal of the driver circuit DRV is connected to a control terminal of the high-side switch HS. A second signal output terminal of the driver circuit DRV is connected to a control terminal of the low-side switch LS.

A first terminal of the high-side switch HS of each of the plurality of power receiving circuits PR1, PR2 is used as the power receiving terminal, and obtains the input current IL from the output voltage VBUSO of the second terminal of the input switch SWIN or the first terminal of the output capacitor Cbuso. If necessary, the input current IL may be divided into a plurality of path currents that respectively flow to the first terminal of the high-side switch HS, the power receiving terminal of the control circuit CTR and the power receiving terminal of the driver circuit DRV.

If each of the plurality of power receiving circuits PR1, PR2 further includes an input capacitor Cin shown in FIG. 3, the plurality of input currents IL flow from the first terminal of the output capacitor Cbuso or the second terminal of the input switch SWIN of the input power supply circuit of the present disclosure respectively to the input capacitors Cin of the plurality of power receiving circuits PR1, PR2 for charging the input capacitors Cin. The first terminal of the high-side switch HS, the power receiving terminal of the control circuit CTR and the power receiving terminal of the driver circuit DRV may obtain an input voltage VIN from the first terminal of the output capacitor Cbuso or respectively obtain the plurality of path currents divided from the input current IL.

In each of the plurality of power receiving circuits PR1, PR2, a second terminal of the high-side switch HS is connected to a first terminal of the low-side switch LS, and a second terminal of the low-side switch LS is grounded. A node between the second terminal of the high-side switch HS and the first terminal of the low-side switch LS is connected to a first terminal of an inductor L. A second terminal of the inductor L is connected to a first terminal of an output capacitor Cout. A second terminal of the output capacitor Cout is grounded.

The main controller circuit 400 may be connected to the control circuits CTR of the plurality of power receiving circuits PR1, PR2. The main controller circuit 400 may, based on the frequencies of the plurality of pulse waves of the main clock signal CLKCR from the clock signal generator circuit 200, output the plurality of main control command signals SCT respectively to the plurality of control circuits CTR of the plurality of power receiving circuits PR1, PR2. Each of the plurality of control circuits CTR of the plurality of power receiving circuits PR1, PR2, according to the main control command signal SCT from the main controller circuit 400, controls or modulates driving on the high-side switch HS and the low-side switch LS for controlling or modulating the output voltage VOUT at an output node between the second terminal of the inductor L and the first terminal of the output capacitor Cout.

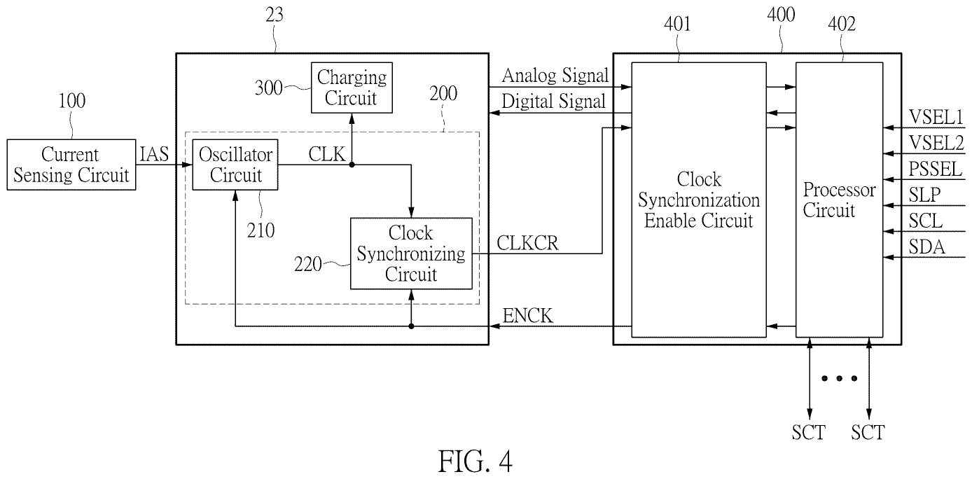

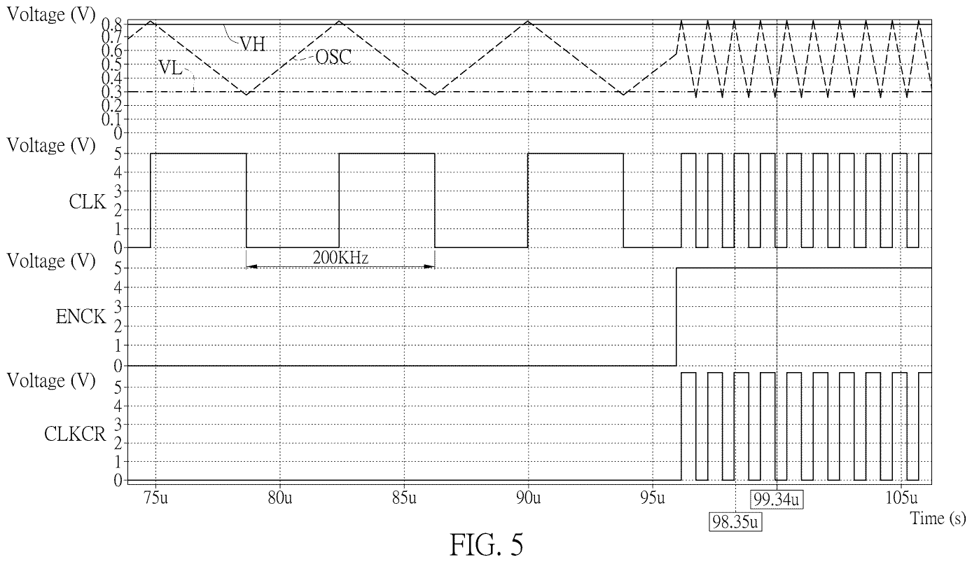

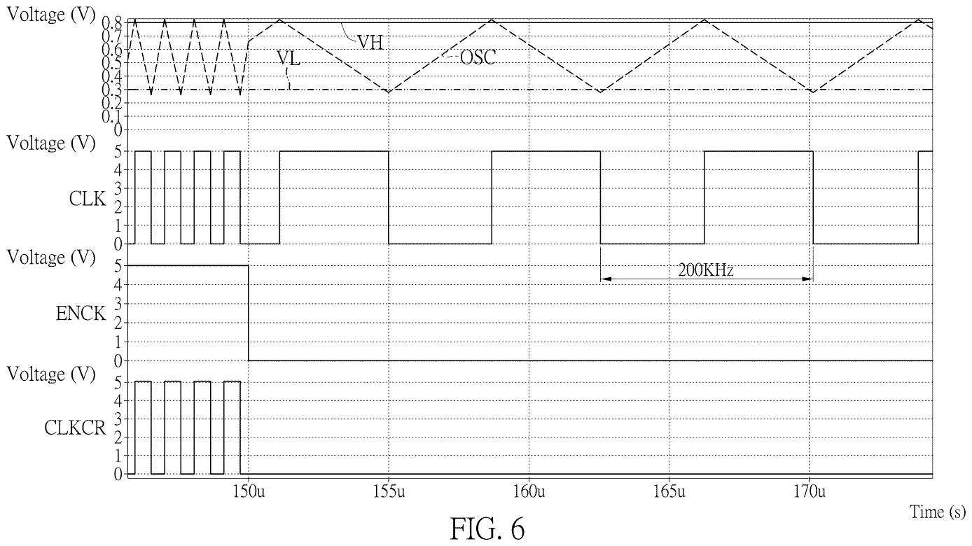

Reference is made to FIG. 4 to FIG. 6, in which FIG. 4 is a circuit diagram of an input power supply circuit having an input power supplying frequency control mechanism according to a fourth embodiment of the present disclosure, FIG. 5 is a waveform diagram of signals of the input power supply circuit having the input power supplying frequency control mechanism according to the first to fourth embodiments of the present disclosure, and FIG. 6 is a waveform diagram of signals of the input power supply circuit having the input power supplying frequency control mechanism according to the first to fourth embodiments of the present disclosure.

The current sensing circuit 100, the clock signal generator circuit 200, the charging circuit 300 and the main controller circuit 400 as shown in FIG. 1 to FIG. 3 may respectively be the same as those shown in FIG. 4. For example, the clock signal generator circuit 200 and the charging circuit 300 may be disposed inside an encapsulation 23 as shown in FIG. 4, but the present disclosure is not limited thereto.

As shown in FIG. 4, the clock signal generator circuit 200 may include an oscillator circuit 210 and a clock synchronizing circuit 220, and the main controller circuit 400 may include a clock synchronization enable circuit 401 and a processor circuit 402.

As shown in FIG. 4, a signal receiving terminal of the clock synchronization enable circuit 401 may be connected to a signal output terminal of the processor circuit 402. An enable output terminal of the clock synchronization enable circuit 401 is connected to a clock enable terminal of the oscillator circuit 210 and a clock enable terminal of the clock synchronizing circuit 220.

A sensing receiving terminal of the oscillator circuit 210 shown in FIG. 4 is connected to the output terminal of the current sensing circuit 100 as shown in FIG. 1 to FIG. 4.

As shown in FIG. 4, a clock output terminal of the oscillator circuit 210 is connected to the input terminal of the charging circuit 300 and a clock receiving terminal of the clock synchronizing circuit 220. A clock output terminal of the clock synchronizing circuit 220 is connected to a clock receiving terminal of the clock synchronization enable circuit 401. A clock output terminal of the clock synchronization enable circuit 401 is connected to a clock receiving terminal of the processor circuit 402.

A plurality of main control terminals of the processor circuit 402 of the main controller circuit 400 shown in FIG. 4 may be connected to the signal input terminal of each of the plurality of power receiving circuits PR1 to PRn shown in FIG. 2, or may be connected to the signal input terminal of the control circuit CTR of each of the plurality of power receiving circuits PR1 to PRn shown in FIG. 3.

If necessary, the clock synchronization enable circuit 401 may receive analog signals from the oscillator circuit 210, the clock synchronizing circuit 220 and the charging circuit 300 inside the encapsulation 23, and may transmit the analog signals to the processor circuit 402.

If necessary, data receiving terminals of the processor circuit 402 shown in FIG. 4 may be connected to one or more external circuits, and the processor circuit 402 may output a processing signal according to a plurality of external data signals VSEL1, VSEL2, PSSEL, SLP, SCL, SDA from the external circuits and the analog signals from the encapsulation 23.

The clock synchronization enable circuit 401 determines whether or not to wake up, according to the processing signal from the processor circuit 402, synchronization of the processor circuit 402 and the charging circuit 300. In detail, the clock synchronization enable circuit 401 determines whether to synchronize a frequency that the processor circuit 402 performs operations and the frequency of charging the voltage of the control terminal of the input switch SWIN according to the processing signal from the processor circuit 402, and accordingly sets a level of a clock enable signal ENCK. If necessary, the clock synchronization enable circuit 401 may output digital signals to the oscillator circuit 210, the clock synchronizing circuit 220 and the charging circuit 300 inside the encapsulation 23.

For example, the operations performed by the processor circuit 402 includes an operation of setting the plurality of main control command signals SCT, an operation of outputting the plurality of main control command signals SCT respectively to the plurality of power receiving circuits PR1 to PRn for controlling the plurality of power receiving circuits PR1 to PRn, an operation of processing the data from the plurality of power receiving circuits PR1 to PRn, and an operation of setting or modulating the plurality of main control command signals SCT according to the data of the plurality of power receiving circuits PR1 to PRn.

In the non-power saving mode or the normal mode, the clock synchronization enable circuit 401 determines to wake up the synchronization of the processor circuit 402 and the charging circuit 300, and accordingly sets the level of the clock enable signal ENCK to be equal to a first level (such as a high level). The first level described herein may be a voltage level or a logic level.

In the non-power saving mode or the normal mode, the oscillator circuit 210, according to the clock enable signal ENCK having the first level (such as the high level) from the clock synchronization enable circuit 401, sets the frequency of each of the plurality of pulse waves of the clock enable signal ENCK to be equal to the preset frequency.

For example, when the oscillator circuit 210 receives the clock enable signal ENCK having the first level (such as the high level), the oscillator circuit 210 generates an oscillating signal OSC having a plurality of preset waveforms (such as triangular waveforms). Then, the oscillator circuit 210 compares each of a plurality of voltages of the plurality of preset waveforms of the oscillating signal OSC respectively with a first preset threshold voltage VL and a second preset threshold voltage VH as shown in FIG. 5 and FIG. 6, and accordingly sets the levels of the charging clock signal CLK for generating the plurality of pulse waves of the charging clock signal CLK. At this time, the frequency of each of the plurality of pulse waves of the charging clock signal CLK is used as the preset frequency such as, but not limited to, 1 MHZ.

In the non-power saving mode or the normal mode, the charging circuit 300 outputs the charging signal CHG to the control terminal of the input switch SWIN, based on the preset frequency of each of the plurality of pulse waves of the charging clock signal CLK from the oscillator circuit 210.

In the non-power saving mode or the normal mode, the clock synchronizing circuit 220 outputs the main clock signal CLKCR having the preset frequency to the clock synchronization enable circuit 401, based on the preset frequency of each of the plurality of pulse waves of the charging clock signal CLK from the oscillator circuit 210.

As shown in FIG. 5 and FIG. 6, when the clock enable signal ENCK is at a high level, the clock synchronization enable circuit 401 receives the clock enable signal ENCK having the plurality of pulse waves from the clock synchronizing circuit 220, and the frequency of each of the plurality of pulse waves of the clock enable signal ENCK is equal to the preset frequency such as 1 MHZ.

It is worth noting that, in the power saving mode, the clock synchronization enable circuit 401 determines whether to wake up or stop the synchronization of the processor circuit 402 and the charging circuit 300, and accordingly sets the level of the clock enable signal ENCK to be equal to an initial level (such as a low level). The initial level described herein may be a voltage level or a logic level.

In the power saving mode, the oscillator circuit 210 receives the clock enable signal ENCK having the initial level (such as the low level) from the clock synchronization enable circuit 401. Under this condition, the oscillator circuit 210 sets the frequencies of the plurality of pulse waves of the charging clock signal CLK according to the input current sensed signal IAS from the current sensing circuit 100 shown in FIG. 1 to FIG. 4, and outputs the charging clock signal CLK to the charging circuit 300.

For example, when the oscillator circuit 210 receives the clock enable signal ENCK having the initial level (such as the low level) from the clock synchronization enable circuit 401, the oscillator circuit 210 sets a plurality of voltages of a plurality of modulation waveforms (such as triangular waveforms) of the oscillating signal OSC according to the input current sensed signal IAS from the current sensing circuit 100 shown in FIG. 1 to FIG. 4. Then, the oscillator circuit 210 compares each of the plurality of voltages of the plurality of modulation waveforms of the oscillating signal OSC respectively with the first preset threshold voltage VL and the second preset threshold voltage VH as shown in FIG. 5 and FIG. 6, and accordingly sets the levels of the charging clock signal CLK for generating the plurality of pulse waves of the charging clock signal CLK. At this time, the frequency of each of the plurality of pulse waves of the charging clock signal CLK is used as a modulation frequency such as, but not limited to, 200 KHZ.

In the power saving mode, the charging circuit 300 outputs the charging signal CHG to the control terminal of the input switch SWIN, based on the frequency of each of the plurality of pulse waves that is set according to the input current sensed signal IAS. The oscillator circuit 210, according to a decrease in the current value of the input current sensed signal IAS, reduces the frequencies of the plurality of pulse waves of the charging clock signal CLK, for example, from 1 MHZ to 200 KHZ. The charging circuit 300 reduces the frequency of charging the voltage of the control terminal of the input switch SWIN based on the reduced frequencies of the charging clock signal CLK, thereby achieving the power saving effect.

That is, in the input power supply circuit of the present disclosure, the frequency of charging the voltage of the control terminal of the input switch SWIN is modulated proportionally or linearly, according to the change in the total input current ISUM that is obtained from the second terminal of the input switch SWIN by the plurality of power receiving circuits PR1, PR2.

It is worth noting that, the change in the frequency of charging the voltage of the control terminal of the input switch SWIN is decreased proportionally or linearly, according to the decrease in the total input current ISUM. Therefore, under the condition that the plurality of power receiving circuits PR1, PR2 obtain sufficient power, the power consumption of the input power supply circuit of the present disclosure is significantly reduced for saving power.

In the power saving mode, the clock synchronizing circuit 220 receives the clock enable signal ENCK having the initial level (such as the low level) from the clock synchronization enable circuit 401.

As shown in FIG. 5 and FIG. 6, when the clock synchronizing circuit 220 receives the clock enable signal ENCK having the low level, the clock synchronizing circuit 220 does not generate any pulse wave in the main clock signal CLKCR according to the plurality of pulse waves of the charging clock signal CLK, and does not output the main clock signal CLKCR to the clock synchronization enable circuit 401, thereby saving more power.

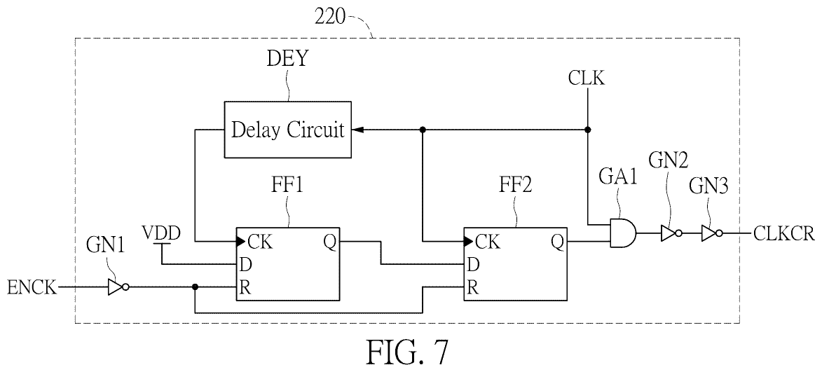

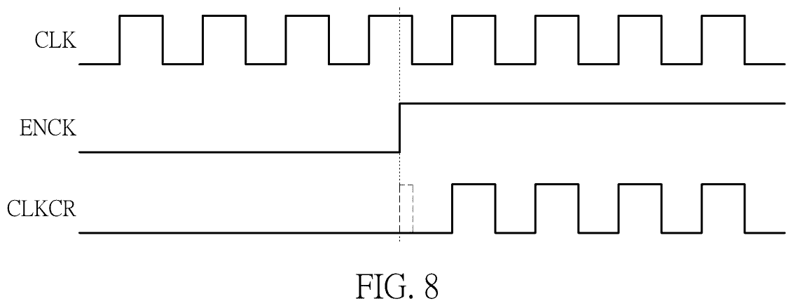

Reference is made to FIG. 7 and FIG. 8, in which FIG. 7 is a circuit diagram of a clock synchronizing circuit of an input power supply circuit having an input power supplying frequency control mechanism according to a fifth embodiment of the present disclosure, and FIG. 8 is a waveform diagram of signals of the clock synchronizing circuit of the input power supply circuit having the input power supplying frequency control mechanism according to the fifth embodiment of the present disclosure.

The clock synchronizing circuit 220 shown in FIG. 4 may be the same as the clock synchronizing circuit 220 shown in FIG. 7.

As shown in FIG. 7, the clock synchronizing circuit 220 includes a first NOT gate GN1, a first flip-flop FF1, a second flip-flop FF2, a AND gate GA1 and a delay circuit DEY. In practice, the AND gate GA1 may be replaced with another type of logic gate. If necessary, the clock synchronizing circuit 220 may further include a second NOT gate GN2 and a third NOT gate GN3. In practice, the NOT gate GN2 and the third NOT gate GN3 may be replaced with buffers or other circuit components.

The first flip-flop FF1 and the second flip-flop FF2 may be D-type flip-flops as shown in FIG. 7, or in practice, may be other types of flip-flops.

An input terminal of the first NOT gate GN1 shown in FIG. 7 is connected to the enable output terminal of the clock synchronization enable circuit 401 of the main controller circuit 400 shown in FIG. 4, and receives the clock enable signal ENCK from the enable output terminal of the clock synchronization enable circuit 401.

A first input terminal D of the first flip-flop FF1 is coupled to a common voltage VDD as shown in FIG. 7, or receives a high logic level “1” in practice. The first input terminal D of the second flip-flop FF2 is connected to an output terminal Q of the first flip-flop FF1.

A second terminal R of the first flip-flop FF1 and the second terminal R of the second flip-flop FF2 are connected to an output terminal of the first NOT gate GN1.

An input terminal of the delay circuit DEY shown in FIG. 7 is used as the clock receiving terminal of the clock synchronizing circuit 220, and is connected to the clock output terminal of the oscillator circuit 210 shown in FIG. 4 and receives the charging clock signal CLK from the clock output terminal of the oscillator circuit 210.

As shown in FIG. 7, a clock receiving terminal of the delay circuit DEY is connected to a clock receiving terminal CK of the first flip-flop FF1.

The clock receiving terminal CK of the second flip-flop FF2 shown in FIG. 7 is connected to the clock output terminal of the oscillator circuit 210 shown in FIG. 4, and receives the charging clock signal CLK from the clock output terminal of the oscillator circuit 210.

A first input terminal of the AND gate GA1 shown in FIG. 7 is connected to the clock output terminal of the oscillator circuit 210 shown in FIG. 4, and receives the charging clock signal CLK from the clock output terminal of the oscillator circuit 210. As shown in FIG. 7, a second input terminal of the AND gate GA1 is connected to the output terminal Q of the second flip-flop FF2, an output terminal of the AND gate GA1 is connected to an input terminal of the second NOT gate GN2, and an input terminal of the third NOT gate GN3 is connected to an output terminal of the second NOT gate GN2.

An output terminal of the third NOT gate GN3 shown in FIG. 7 is connected to the clock receiving terminal of the clock synchronization enable circuit 401 of the main controller circuit 400 shown in FIG. 4.

As shown in FIG. 7, after a delay time is elapsed, since the clock output terminal of the oscillator circuit 210 outputs the charging clock signal CLK having the plurality of pulse waves to the delay circuit DEY, the delay circuit DEY transmits the charging clock signal CLK to the clock receiving terminal CK of the first flip-flop FF.

When the clock synchronization enable circuit 401 determines to wake up the synchronization of the processor circuit 402 and the charging circuit 300 as shown in FIG. 4, the input terminal of the first NOT gate GN1 shown in FIG. 7 receives the clock enable signal ENCK having the high level from the clock synchronization enable circuit 401 shown in FIG. 4.

It is worth noting that, when the clock synchronization enable circuit 401 shown in FIG. 4 intends to save the power of the input power supply circuit of the present disclosure, the clock synchronization enable circuit 401 determines not to wake up the synchronization of the processor circuit 402 and the charging circuit 300. Under this condition, the input terminal of the first NOT gate GN1 shown in FIG. 7 receives the clock enable signal ENCK having the low level from the clock synchronization enable circuit 401 shown in FIG. 4.

Then, the first NOT gate GN1 inverts the clock enable signal ENCK having the low level into the clock enable signal ENCK having the high level.

When the second terminal R of the first flip-flop FF1 receives the clock enable signal ENCK having the high level from the output terminal of the first NOT gate GN1, the first input terminal D of the first flip-flop FF1 receives the common voltage VDD having a high voltage level, and the clock receiving terminal CK of the first flip-flop FF1 receives the charging clock signal CLK having the high level from the delay circuit DEY, the output terminal Q of the first flip-flop FF1 outputs a first wakeup signal having the high level to the first input terminal D of the second flip-flop FF2.

Then, when the first input terminal D of the second flip-flop FF2 receives the first wakeup signal having the high level, the second terminal R of the second flip-flop FF2 receives the clock enable signal ENCK having the high level from the output terminal of the first NOT gate GN1, and the clock receiving terminal CK of the second flip-flop FF2 receives the charging clock signal CLK having the high level from the delay circuit DEY, the output terminal Q of the second flip-flop FF2 outputs a second wakeup signal having the high level to the second input terminal of the AND gate GA1.

Then, when the second input terminal of the AND gate GA1 receives the second wakeup signal having the high level from the output terminal Q of the second flip-flop FF2 and the first input terminal of the AND gate GA1 receives the charging clock signal CLK having the high level from the clock output terminal of the oscillator circuit 210, the AND gate GA1 outputs the main clock signal CLKCR having the high level sequentially through the second NOT gate GN2 and the third NOT gate GN3 to the clock receiving terminal of the clock synchronization enable circuit 401.

It is worth noting that, the delay circuit DEY delays a time point at which the clock receiving terminal CK of the first flip-flop FF1 receives the charging clock signal CLK outputted by the oscillator circuit 210. As a result, as shown in FIG. 5, after the clock enable signal ENCK transits from the initial level (such as the low level) into the first level (such as the high level), the clock synchronizing circuit 220 generates the plurality of pulse waves each having a complete waveform in the main clock signal CLKCR only according to the plurality of pulse waves of the charging clock signal CLK except for a first one of the plurality of pulse waves of the charging clock signal CLK, and outputs the main clock signal CLKCR to the clock receiving terminal of the clock synchronization enable circuit 401. Therefore, a first incomplete pulse wave, which is also called a glitch, as marked by a dotted line in FIG. 8, is prevented from being generated in the main clock signal CLKCR. The clock synchronization enable circuit 401 normally operates according to the plurality of pulse waves each having the complete waveform in the main clock signal CLKCR.

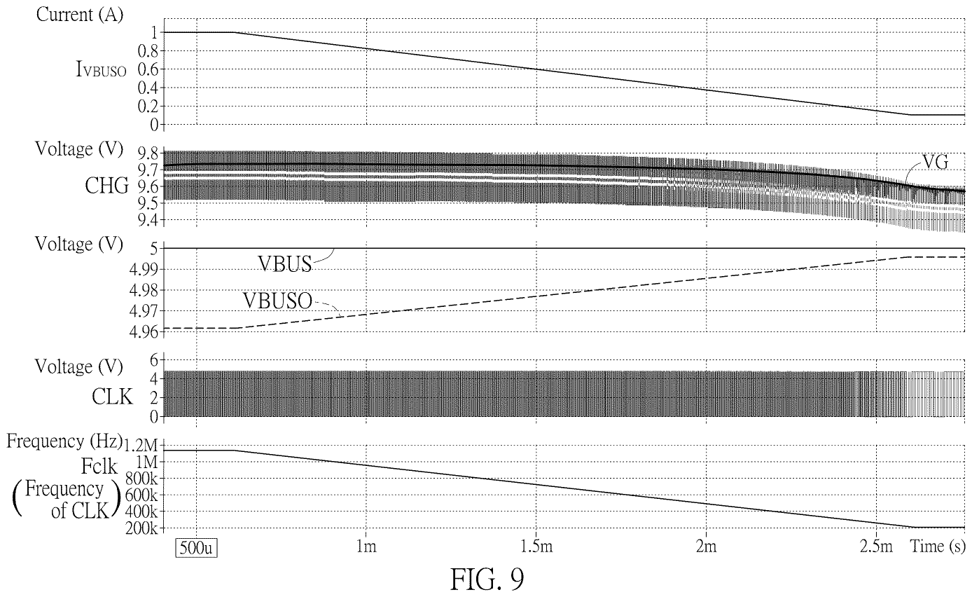

Reference is made to FIG. 9, which is a waveform diagram of signals of the input power supply circuit having the input power supplying frequency control mechanism according to the first to fifth embodiments of the present disclosure.

The input power supply circuit of the present disclosure shown in FIG. 1, FIG. 2 or FIG. 3 may receive the input voltage VBUS shown in FIG. 9, and may generate a supply current IVBUSO, a voltage VG, the charging signal CHG, the charging clock signal CLK and the output voltage VBUSO as shown in FIG. 9.

When the input power supply circuit of the present disclosure continually receives the input voltage VBUS having a constant volage value and the supply current IVBUSO that is obtained from the output voltage VBUSO of the output capacitor Cbuso of the input power supply circuit of the present disclosure by the plurality of power receiving circuits PR1 to PRn is gradually reduced from 1 A to 100 mA, the output voltage VBUSO of the output capacitor Cbuso is gradually increased.

It is worth noting that, when the supply current IVBUSO that is obtained from the output voltage VBUSO of the output capacitor Cbuso of the input power supply circuit of the present disclosure by the plurality of power receiving circuits PR1 to PRn is gradually reduced from 1 A to 100 mA, the clock signal generator circuit 200 of the input power supply circuit of the present disclosure reduces a frequency Fclk of each of the plurality of pulse waves of the charging clock signal CLK as shown in FIG. 9. The charging circuit 300, based on the reduced frequency Fclk of each of the plurality of pulse waves of the charging clock signal CLK, gradually reduces a frequency of supplying the charging signal CHG to the control terminal of the input switch SWIN. As a result, the voltage VG of the control terminal of the input switch SWIN is gradually reduced.

That is, when the supply current IVBUSO that is obtained from the output capacitor Cbuso of the input power supply circuit of the present disclosure by the plurality of power receiving circuits PR1 to PRn (that are the power converters) is reduced, operational frequencies of the charging circuit 300, the input switch SWIN and the clock signal generator circuit 200 of the input power supply circuit of the present disclosure are reduced, thereby achieving the power saving effect.

In conclusion, the present disclosure provides the input power supply circuit having the input power supplying frequency control mechanism. In the input power supply circuit of the present disclosure, the charging circuit reduces the frequency of charging the voltage of the control terminal of the input switch, according to the decrease in the total input current that is obtained from the second terminal of the input switch by the plurality of power receiving circuits (such as the power converters). As a result, the input power supply circuit of the present disclosure only supplies an appropriate amount of power but not excessive power to the plurality of power receiving circuits. Therefore, power is prevented from being unnecessarily consumed in the input power supply circuit of the present disclosure for effectively saving the power. Furthermore, if the input power supply circuit of the present disclosure further includes the main controller circuit, the clock signal generator circuit stops supplying the main clock signal to the main controller circuit in the power saving mode, thereby saving more power.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An input power supply circuit having an input power supplying frequency control mechanism, comprising:
an input switch, wherein a first terminal of the input switch is coupled to an input voltage, and a second terminal of the input switch is connected to a power receiving terminal of each of a plurality of power receiving circuits;
a current sensing circuit connected to the second terminal of the input switch and configured to sense a total input current flowing from the second terminal of the input switch to output an input current sensed signal;
a clock signal generator circuit connected to the current sensing circuit and configured to set a frequency of each of a plurality of pulse waves of a charging clock signal according to the input current sensed signal; and
a charging circuit connected to the clock signal generator circuit and a control terminal of the input switch, and configured to output a charging signal to the control terminal of the input switch based on the frequency of each of the plurality of pulse waves of the charging clock signal.

2. The input power supply circuit according to claim 1, wherein the current sensing circuit includes:
a current sensing amplifier connected to the second terminal of the input switch and configured to sense the total input current and multiply the total input current by a preset gain to output the input current sensed signal.

3. The input power supply circuit according to claim 1, further comprising:
an output capacitor, wherein a first terminal of the output capacitor is connected to the second terminal of the input switch, and a second terminal of the output capacitor is grounded.

4. The input power supply circuit according to claim 1, wherein the plurality of power receiving circuits include a plurality of power converters.

5. The input power supply circuit according to claim 1, further comprising:
a main controller circuit connected to the clock signal generator circuit, and configured to control the clock signal generator circuit to set the frequency of each of the plurality of pulse waves of the charging clock signal according to the input current sensed signal in a power saving mode.

6. The input power supply circuit according to claim 5, wherein the main controller circuit is configured to control the clock signal generator circuit to set the frequency of each of the plurality of pulse waves of the charging clock signal to be equal to a preset frequency in a normal mode.

7. The input power supply circuit according to claim 6, wherein the main controller circuit is configured to output a main clock signal having the preset frequency according to the charging clock signal in the normal mode;
wherein the main controller circuit is configured to control the plurality of power receiving circuits or process data from the plurality of power receiving circuits based on the preset frequency of the main clock signal in the normal mode.

8. The input power supply circuit according to claim 7, wherein the main controller circuit is configured to control the clock signal generator circuit to stop outputting the main clock signal in the power saving mode.

9. The input power supply circuit according to claim 5, wherein the clock signal generator circuit includes:
an oscillator circuit connected to the main controller circuit, the current sensing circuit and the charging circuit;
wherein, when the oscillator circuit receives a clock enable signal having an initial level from the main controller circuit, the oscillator circuit sets the frequency of each of the plurality of pulse waves of the charging clock signal according to the input current sensed signal, and outputs the charging clock signal to the charging circuit.

10. The input power supply circuit according to claim 9, wherein the clock signal generator circuit further includes:
a clock synchronizing circuit connected to the oscillator circuit and the main controller circuit;
wherein, when the clock synchronizing circuit receives the clock enable signal having the initial level from the main controller circuit, the clock synchronizing circuit does not output a main clock signal to the main controller circuit according to the charging clock signal.

11. The input power supply circuit according to claim 10, wherein, when the oscillator circuit receives the clock enable signal having a first level from the main controller circuit, the oscillator circuit sets the frequency of each of the plurality of pulse waves of the charging clock signal to be equal to a preset frequency.

12. The input power supply circuit according to claim 11, wherein, when the clock synchronizing circuit receives the clock enable signal having the first level from the main controller circuit, the clock synchronizing circuit outputs the main clock signal having the preset frequency to the main controller circuit according to the charging clock signal having the preset frequency.

13. The input power supply circuit according to claim 12, wherein, after the clock enable signal transits from the initial level to the first level, the clock synchronizing circuit outputs the main clock signal according to the plurality of pulse waves of the charging clock signal except for a first one of the plurality of pulse waves of the charging clock signal.

14. The input power supply circuit according to claim 12, wherein the main controller circuit includes:
a clock synchronization enable circuit connected to the clock synchronizing circuit and the oscillator circuit, wherein the clock synchronization enable circuit is configured to output the clock enable signal having the first level and receive the main clock signal from the clock synchronizing circuit in a normal mode, and configured to output the clock enable signal having the initial level in the power saving mode; and
a processor circuit connected to the clock synchronization enable circuit, and configured to control the plurality of power receiving circuits or process data from the plurality of power receiving circuits, based on frequencies of a plurality of pulse waves of the main clock signal from the clock synchronization enable circuit.

15. The input power supply circuit according to claim 14, wherein the processor circuit is configured to output a processing signal according to a plurality of external data signals, and the clock synchronization enable circuit is configured to set a level of the clock enable signal according to the processing signal.

16. The input power supply circuit according to claim 10, wherein the clock synchronizing circuit includes:
a first NOT gate, wherein an input terminal of the first NOT gate is connected to the main controller circuit and configured to receive the clock enable signal from the main controller circuit;
a first flip-flop, wherein a first input terminal of the first flip-flop is coupled to a common voltage, and a second input terminal of the first flip-flop is connected to an output terminal of the first NOT gate;
a second flip-flop, wherein a first input terminal of the second flip-flop is connected to an output terminal of the first flip-flop, a second input terminal of the second flip-flop is connected to the output terminal of the first NOT gate, and a clock receiving terminal of the second flip-flop is connected to the oscillator circuit and configured to receive the charging clock signal from the oscillator circuit;
a delay circuit connected to the oscillator circuit, and configured to transmit the charging clock signal to a clock receiving terminal of the first flip-flop after a period of time is elapsed since the oscillator circuit output the charging clock signal; and
an AND gate, wherein a first input terminal of the AND gate is connected to the oscillator circuit and configured to receive the charging clock signal from the oscillator circuit, a second input terminal of the AND gate is connected to an output terminal of the second flip-flop, and an output terminal of the AND gate is configured to output the main clock signal to the main controller circuit connected thereto.

17. The input power supply circuit according to claim 16, wherein the clock synchronizing circuit further includes:
a second NOT gate, wherein an input terminal of the second NOT gate is connected to the output terminal of the AND gate; and
a third NOT gate, wherein an input terminal of the third NOT gate is connected to an output terminal of the second NOT gate, and an output terminal of the third NOT gate is configured to output the main clock signal to the main controller circuit connected thereto.
